(19) United States
(12) Patent Application Publication
(10) Pub. No.: US 2011/0198118 A1
(43) Pub. Date: Aug. 18, 2011

(54) Magnet wire

(75) Inventors: Tsang-Tse Fang, Tainan (TW); Han-Yang Chung, Jhongli (TW); Chi-Feng Hung, Tainan (TW); Ting-I Lu, Rende Hsiang (TW); Kuang-Chiang Chou, Tainan (TW); Pa-Kuel Chuang, Tainan (TW); Chun-Hung Chen, Tainan (TW); Jung-Kun Chiu, Tainan (TW); Shang-Hui Shen, Kuan Miao Hsiang (TW)

(73) Assignee: TA YA ELECTRIC WIRE & CABLE CO., LTD., Tainan Hsien (TW)

(21) Appl. No.: 12/656,796

(22) Filed: Feb. 17, 2010

(51) Int. Cl. H05K 9/00; H01R 43/00

(52) U.S. Cl. 174/391; 29/825; 335/284

(57) ABSTRACT

A magnet wire has a conductor and a coating layer. The coated layer is coated around the conductor and has at least one magnetic coating layer; and at least one insulating coating layer. The magnetic coating layer has non-conductive magnetic material. The insulating coating layer and the magnetic coating layer are formed alternately. The alternative structure of the magnetic coating layer and the insulating coating layer prevent precipitation of magnetic material and efficiently offsets the interference between conductors after electricity is supplied, which inhibits occurrence of eddy current and lowers alternative current (AC) resistance.

### BACKGROUND OF THE INVENTION

1. Field of Invention The present invention relates to a magnetic wire, and more particularly to a magnetic wire that compensates induced interference currents to overcome proximity effect and skin effect, which lowers high-frequency alternating current (AC) resistance and saves energy.

2. Description of the Related Art

Coil, usually used in a transformer or other electronic device, controls inductor and transform voltage with electromagnetic induction. However, energy is eliminated during every transformation between electricity and magnetism. Especially in a high frequency operation, energy elimination is more apparent, which is resulted from “eddy current loss” due to “iron loss” in the iron core and “copper loss” of enameled wire. Eddy current is occurred when a conductor is exposed to a changing magnetic field due to alternating current (AC), so an induced current, which flows inversely in the conductor, is generated to oppose the change. Accordingly, conductor impedance is increased. Especially when frequency of the current is increased, conductor impedance becomes higher.

Iron loss can be resolved by changing material or structure of the iron core. Material with large relative permeability (i.e. low magnetoresistance) can be used to lower the effect from the eddy current. Furthermore, the iron core can be laminated by multiple thin silicon steel sheets, which are insulated from each other. The thinner a thickness of each silicon steel sheet has, the less effect caused by eddy current is occurred. In addition, silicon efficiently reduce conductivity of the iron core when it is added into the iron core and lowering iron loss due to the eddy current.

Besides resistance loss of the copper wire, copper loss is also induced by skin effect and proximity effect in a high-frequency operation. The skin effect is due to the conductor affected by eddy current in a high-frequency operation, so that the current density near a surface of the conductor is greater than that at its core. Therefore, AC resistance of the conductor is increased. The proximity effect is due to an interaction between a conductor with its own magnetic field and an adjacent conductor with another magnetic field when the adjacent conductor carries high-frequency AC. Eddy current is occurred in the adjacent conductor. Therefore, copper loss becomes serious and affects transformation between energies. Accordingly, associated industries devote to developing a product with reduced loss and increased transformation efficiency.

For lowering the resistance loss, the enameled wire can be made of high-purity copper or material with low resistance such as pure silver wire or a silver-plated wire. Alternatively, lengthening a diameter of the enameled wire can also lower the resistance loss. However, the foregoing policies cost a lot. Furthermore, eddy current is the main reason to make the AC resistance increased, so if electromagnetic effect, which induces eddy current, can be restrained, the resistance loss can be reduced. A conventional method for suppressing eddy current comprises twisting a bunch of conductors to offset induction electromotive forces from each other, which suppresses eddy current, lowers AC resistance and reduces temperature rise of coil. However, twisted enameled wires consist of multiple conductors that each is covered with an insulating cover, so the conventional method is complicated and expensive and easily makes conductors broken or results in poor soldering ability at ends of each conductor.

In 2000, CN1242582A, which is invalid now, disclosed an enamel-covered wire characterized in that wire surface and coil gaps are covered and filled by adhesive agent containing more than 50% magnetic powder to be made into coil with magnetic body. It can shorten magnetic path, reduce leakage magnetism and reduce consumption of iron core or replace the iron core. However, this patent does not mention any mean for suppressing eddy current and AC resistance.

In 2002, TOTOKU ELECTRIC filed a patent, JP 2002-231060, which discloses a conductor coated with an insulating coating including 50% iron (Fe) powder, nickel (Ni) powder, Fe—Ni alloy powder or the like. Therefore, a large amount of metallic powder surrounds the conductor to form a shielding layer, which results in shielding effect to increase Q-characteristics of a high-frequency coil. However, although the insulating coating with metallic powder possesses high magnetic susceptibility, it has high conductivity and is not insulation anymore. Furthermore, the metallic powder has large specific gravity and easily precipitates in the insulating coating, so this strategy cannot be applied to long-term mass production operation and also cannot keep characteristics of normal enameled wire.

US 2006/0165983 discloses a magnetoresistant enameled wire coated with a coating. The coating comprises magnetoresistant material with 0.3˜30% solid-content of the coating to keep characteristics of normal enameled wire. However, the magnetoresistant enameled wire is capable of minimizing the energy loss as well as inhibiting temperature rise, but wire resistance is only reduced by 0.07%. Furthermore, because the magnetoresistant material cannot distribute homogeneously in the coating, content of magnetoresistant material cannot be higher than 30%.

To overcome the shortcomings, the present invention provides a magnet wire to mitigate or obviate the aforementioned.

### SUMMARY OF THE INVENTION

The primary objective of the present invention is to provide a magnetic wire that compensates induced interference currents to overcome proximity effect and skin effect, which lowers high-frequency alternating current (AC) resistance and saves energy.

To achieve the objective, the magnet wire in accordance with the present invention comprises a conductor and a coating layer. The coated layer is coated around the conductor and has at least one magnetic coating layer; and at least one insulating coating layer. The magnetic coating layer has non-conductive magnetic material. The insulating coating layer and the magnetic coating layer are formed alternatively.

The alternative structure of the magnetic coating layer and the insulating coating layer prevent precipitation of magnetic material and efficiently offsets the interference between conductors after electricity is supplied, which inhibits occurrence of eddy current and lowers alternative current (AC) resistance.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional end view of a first variant of a magnet wire in accordance with the present invention;

FIG. 2 is a cross sectional end view of a second variant of a magnet wire in accordance with the present invention;

FIG. 3 is a cross sectional end view of a third variant of a magnet wire in accordance with the present invention;

FIG. 4 is a cross sectional end view of a fourth variant of a magnet wire in accordance with the present invention;

FIG. 5 is a cross sectional end view of a fifth variant of a magnet wire in accordance with the present invention; and

FIG. 6 is a flow chart of a method for manufacturing a magnetic enameled wire in accordance with the present invention.

### DETAILED DESCRIPTION OF THE INVENTION

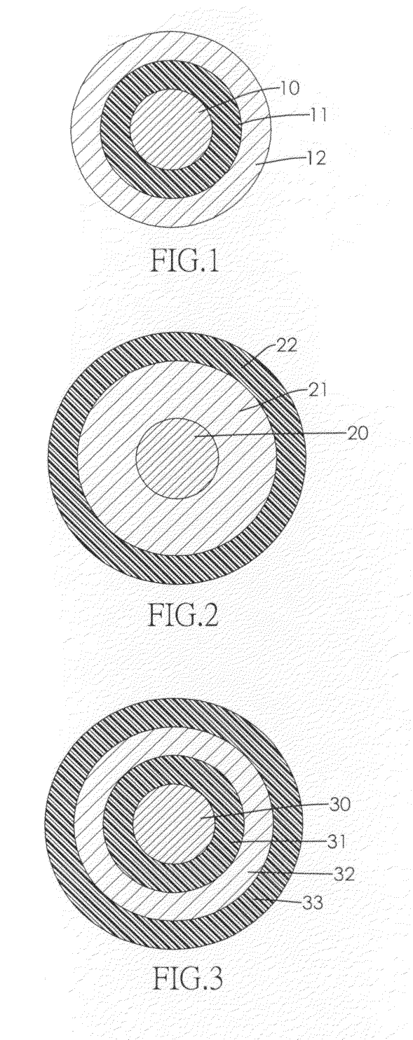

With reference to FIG. 1, a magnet wire in accordance with the present invention has a conductor (10) and a coating layer.

The conductor (10) is a cylindrical bare copper wire, flat bare copper wire, copper clad aluminum wire, aluminum wire, tinned copper wire or alloy metallic wire, enameled wire, multiple-layer insulating wire or other wire that is known by the person with ordinary skilled in the art.

The coating layer is coated around the conductor (10) and has at least one magnetic coating layer (12) and at least one insulating coating layer (11).

The magnetic coating layer (12) has insulating coating and non-conductive magnetic material. The magnetic coating layer (12) is formed by surface treating the non-conductive magnetic material with surfactant, such as organic silane or oleic acid; and homogeneously blending the non-conductive magnetic material and the insulating coating.

The insulating coating is made of polyester, polyimide, polyurethane, poly(amide-imide), poly(ester-imide) or the like. The non-conductive magnetic material distributed homogeneously in the insulating coating and has 30˜50% solid content relative to the insulating coating.

The non-conductive magnetic material comprises ferromagnetism or ferrimagnetism and includes, but not limited to γ-Fe₂O₃, Fe₃O₄, Ni—Zn ferrite, Mn—Zn ferrite, Mg—Zn ferrite, Ba ferrite, Sr ferrite or the like. The non-conductive magnetic material comprises multiple particles with an average size of 3 μm.

Each insulating coating layer (11) is adjacent to the magnetic coating layer (12) or is formed between two magnetic coating layers (12) and allowing the insulating coating layer (11) and the magnetic coating layer (12) to be formed alternately. The insulating coating layer (11) is made of polyester, polyimide, polyurethane, poly(amide-imide), poly(ester-imide) or the like.

With reference to FIG. 1 again, the magnet wire in a first variant consists of a conductor (10) made of copper, an insulating coating layer (11) coated around the conductor (10) and a magnetic coating layer (12) coated around the insulating coating layer (11). Therefore, the magnet wire in the first variant has one layer of insulating coating layer (11) and one layer of magnetic coating layer (12).

With reference to FIG. 2, the magnet wire in a second variant consists of a conductor (20) made of copper, a magnetic coating layer (21) coated around the conductor (20) and an insulating coating layer (22) coated around the magnetic coating layer (21). Therefore, the magnet wire in the second variant has one layer of magnetic coating layer (21) and one layer of insulating coating layer (22).

With reference to FIG. 3, the magnet wire in a third variant consists of a conductor (30) made of copper, a first insulating coating layer (31) coated around the conductor (30), a magnetic coating layer (32) coated around the first insulating coating layer (31) and a second insulating coating layer (33) coated around the magnetic coating layer (32). Therefore, the magnet wire in the third variant has two layers of insulating coating layer (31,33) and one layer of magnetic coating layer (32).

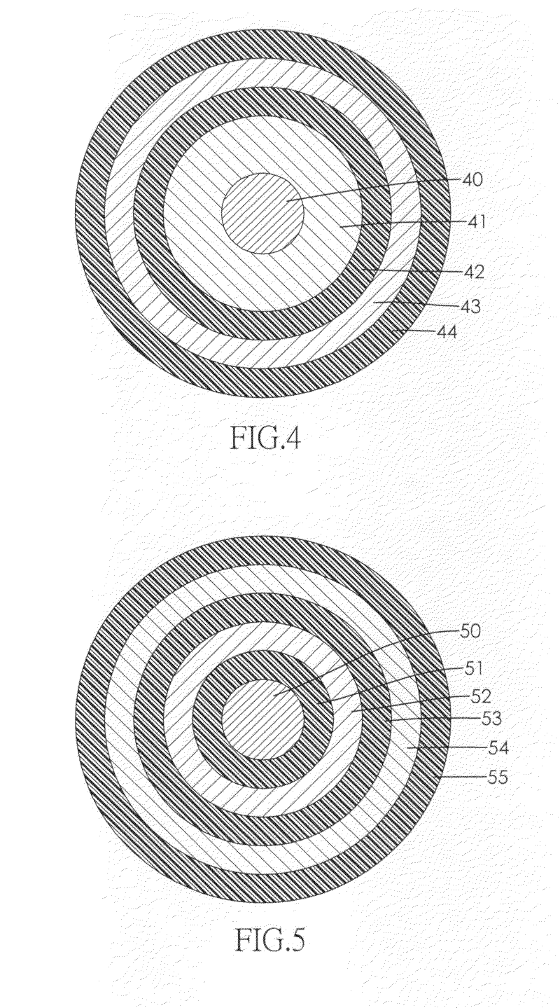

With reference to FIG. 4, the magnet wire in a fourth variant consists of a conductor (40) made of copper, a first magnetic coating layer (41) coated around the conductor (40), a first insulating coating layer (42) coated around the first magnetic coating layer (41), a second magnetic coating layer (43) coated around the first insulating coating layer (42), and a second insulating coating layer (44) coated around the second magnetic coating layer (43). Therefore, the magnet wire in the fourth variant has two layers of magnetic coating layer (41, 43) and two layers of insulating coating layer (42, 44).

With reference to FIG. 5, the magnet wire in a fifth variant consists of a conductor (50) made of copper, a first insulating coating layer (51) coated around the conductor (50), a first magnetic coating layer (52) coated around the first insulating coating layer (51), a second insulating coating layer (53) coated around the first magnetic coating layer (52), a second magnetic coating layer (54) coated around the second insulating coating layer (53) and a third insulating coating layer (55) coated around the second magnetic coating layer (54). Therefore, the magnet wire in the third variant has three layers of insulating coating layer (51, 53, 55) and two layers of magnetic coating layer (52, 54).

According to the foregoing variants of the magnet wire, it should be understood that the coating layer may comprise one or more insulating coating layer and one or more magnetic coating layer. When the coating layer comprises two or more magnetic coating layers, those layers may consist of magnetic materials with the same pole or opposed poles. There must be an insulating coating layer formed between each two magnetic coating layers.

A high-frequency inductive electronic element is also provided in accordance with the present invention, which comprises the foregoing magnet wire of the present invention. The high frequency is from 10 k Hz to 500 k Hz. Preferably, the high frequency is from 50 k Hz to 200 k Hz. The high-frequency electronic element comprises high-frequency inductor, high-frequency transformer, high-frequency electrical coil, power supply or the like.

A method for manufacturing the foregoing magnet wire in accordance with the present invention comprises providing a conductor; coating the conductor with a coating layer that each layer is rapidly coated for more than one times; and instantly drying the coating layer at high temperature (440˜500° C.) to form the magnet wire.

The step of coating the conductor with a coating layer comprises using a die to apply the insulating coating layer, which is able to control a thickness of the insulating coating layer, so a distance between each two magnetic coating layers and extent of lowering the AC resistance can be adjusted by the thickness of the insulating coating layer.

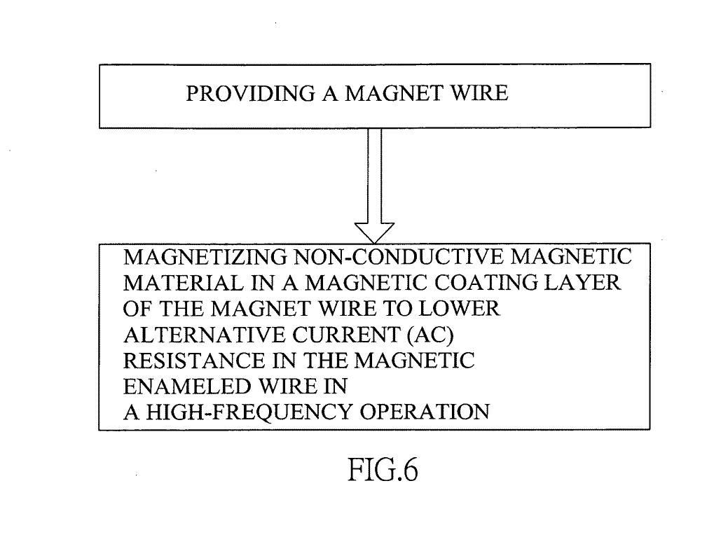

With reference to FIG. 6, a method for manufacturing a magnetic enameled wire in accordance with the present invention comprises providing the foregoing magnet wire; and magnetizing the non-conductive magnetic material in the magnetic coating layer to lower efficiently the AC resistance in the magnetic enameled wire in a high-frequency operation.

The alternate structure of the magnetic coating layer and the insulating coating layer prevent precipitation of magnetic material and efficiently offsets the interference between conductors after electricity is supplied, which inhibits occurrence of eddy current and lowers alternative current (AC) resistance. Moreover, the method for manufacturing the magnet wire includes applying a coating layer rapidly for many times; and instantly drying the coating layer at high temperature, so the solid content of magnetic material can be reached to 30˜50% and the magnetic material is able to evenly distributed in the insulating coating, which cannot be achieved in the prior art. Additionally, after magnetize the non-conductive magnetic material, the magnetic enameled wire has improved efficiency to offset the interference between conductors.

### EXAMPLE

### Material and Equipment

1. Polyurethane coating, PU-130-45, purchased from Tong Hsieh Chemical Industrial Co., Ltd. has viscosity of 0.5 Pa·second at 30° C. and solid content of 45%.

2. γ-Fe₂O₃, γ-MRD, purchased from Titan Kogyo LTD., Japan has an axial length of 0.5 μm and an axial ratio of 7.

3. Oleic acid, CAS NO. 112-80-1, purchased from Shimakyu's Pure Chemicals, Osaka, Japan has a concentration of 98%.

4. Inductor, capacitor and resistance meter (LCR meter), E4980A, purchased from Agilent Technologies, Inc., US has a frequency measuring range from 20 Hz to 2M Hz.

### Manufacture Process

### Comparative Example 1

Polyurethane coating without any magnetic material was coated around a copper wire (0.31 mm) with a die for twelve times with a line speed of 60˜70 meter/min and the polyurethane coating was cured at 440˜500° C. to form a conventional magnet wire with a single insulating layer.

### Example 1

20 part of γ-Fe₂O₃ was added into 100 part of polyurethane coating and they were blended for 24 hours with ball mill to form a magnetic material. The magnetic material was coated around a copper wire (0.31 mm) with a die for five times with a line speed of 60˜70 meter/min to form a magnetic coating layer; then polyurethane coating was coated around the magnetic coating layer with a die for five times with a line speed of 60˜70 meter/min to form an insulating coating layer; and the magnetic coating layer and the insulating coating layer were cured at 440˜500° C. to form a magnet wire with a layer of magnetic coating layer and a layer of insulating coating layer.

### Example 2

20 part of γ-Fe₂O₃ was surface treated by 5 part of oleic acid, then was added into 100 part of polyurethane coating and they were blended for 24 hours with ball mill to form a magnetic material. A magnet wire with a layer of magnetic coating layer and a layer of insulating coating layer was produced using the same steps as described in example 1.

### Example 3

15 part of γ-Fe₂O₃ was added into 100 part of polyurethane coating and they were blended for 24 hours with ball mill to form a magnetic material. A magnet wire with a layer of magnetic coating layer and a layer of insulating coating layer was produced using the same steps as described in example 1.

Results:

The magnet wires of comparative example and examples of the present invention were tested according to NEMA MW-75C and presented characteristics shown in Table 1.

TABLE 1
Test and results for comparative example 1 and examples of the present invention

| Test | Comp. Ex. 1 | Ex. 1 | Ex. 2 | Ex. 3 |
|---|---|---|---|---|
| Appearance | good | good | good | good |
| Adherence | good | good | good | good |
| Flexibility | good | good | good | good |
| Elongation(%) | 30.6 | 30.9 | 32.8 | 34.0 |
| Single-direction scrape resistance | 1480 | 1419 | 1187 | 1196 |
| Heat shock | good | good | good | good |
| Thermoplastic flow (° C.) | 251 | 246 | 238 | 222 |
| Solderability | good | good | good | good |
| Dielectric breakdown voltage (KV) | 9.42 | 8.43 | 8.60 | 8.97 |
| Conductor resistance(Ω/km) | 232.9 | 228.4 | 227.5 | 228.5 |
| 200 kHz AC resistance(Ω)*¹ | 1.65 | 1.53 | 1.60 | 1.56 |
| Lowering ratio of AC resistance(%)*² | — | 7.3 | 3.0 | 5.5 |

^{*1}An 110-cm enameled wire was tightly wound around inductance bobbin with an outer diameter of 8.0 mm, an inner diameter of 7.0 mm for 34 circles; ferrite core (RM7) was mounted in the inductance bobbin; and AC resistance at 200 kHz was measured by inductor, capacitor and resistance meter (LCR meter) at 1 V °
^{*2}Lowering ratio of AC resistance = [(AC resistance at 200 kHz of comparative example 1 - AC resistance at 200 kHz of example)/AC resistance at 200 kHz of comparative example 1]*100% °

The magnet wire of the present invention in each of examples 1 to 3 has lower AC resistance than the conventional magnet wire of comparative example 1. Especially, example 1 has highest lowering ratio of AC resistance, so the present invention is confirmed to lower the AC resistance and resolves disadvantages in the prior art.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A magnet wire comprising:
a conductor; and
a coating layer coated around the conductor and having
at least one magnetic coating layer having non-conductive magnetic material; and
at least one insulating coating layer; and
wherein the insulating coating layer and the magnetic coating layer are formed alternately.

2. The magnet wire as claimed in claim 1, wherein the magnetic coating layer further has insulating coating and the non-conductive magnetic material distributed homogeneously in the insulating coating and has 30˜50% solid content relative to the insulating coating;
wherein the magnet wire is manufactured by the method comprising providing the conductor; coating the conductor with the coating layer that each layer is rapidly coated for more than one times; and instantly drying the coating layer at 440˜500° C. to form the magnet wire.

3. The magnet wire as claimed in claim 1, wherein the magnetic coating layer is formed by surface treating the non-conductive magnetic material with surfactant; and homogeneously blending the non-conductive magnetic material and the insulating coating.

4. The magnet wire as claimed in claim 3, wherein the surfactant is selected from the group consisting of silane and oleic acid.

5. The magnet wire as claimed in claim 2, wherein the magnetic coating layer is formed by surface treating the non-conductive magnetic material with surfactant; and homogeneously blending the non-conductive magnetic material and the insulating coating.

6. The magnet wire as claimed in claim 5, wherein the surfactant is selected from the group consisting of silane and oleic acid.

7. The magnet wire as claimed in claim 2, wherein
the non-conductive magnetic material of the magnetic coating layer comprises ferromagnetism or ferrimagnetism and the non-conductive magnetic material comprises multiple particles with an average size of 3 μm;
the insulating coating of the magnetic coating layer is made of polyester, polyimide, polyurethane, poly(amide-imide) or poly(ester-imide); and
the insulating coating layer is made of polyester, polyimide, polyurethane, poly(amide-imide) or poly(ester-imide).

8. The magnet wire as claimed in claim 7, wherein the non-conductive magnetic material is selected from the group consisting of γ-Fe₂O₃, Fe₃O₄, Ni—Zn ferrite, Mn—Zn ferrite, Mg—Zn ferrite, Ba ferrite and Sr ferrite.

9. The magnet wire as claimed in claim 2, wherein the conductor is selected from the group consisting of cylindrical bare copper wire, flat bare copper wire, copper clad aluminum wire, aluminum wire, tinned copper wire and alloy metallic wire.

10. A high-frequency inductive electronic element, comprises a magnet wire having:
a conductor; and
a coating layer coated around the conductor and having
at least one magnetic coating layer having non-conductive magnetic material; and
at least one insulating coating layer; and
wherein the insulating coating layer and the magnetic coating layer are formed alternately.

11. The high-frequency inductive electronic element as claimed in claim 10, being selected from the group consisting of high-frequency inductor, high-frequency transformer, high-frequency electrical coil and power supply.

12. The high-frequency inductive electronic element as claimed in claim 10, wherein the high-frequency inductive electronic is capable of operating in a high frequency that is from 10 k Hz to 500 k Hz.

13. The high-frequency inductive electronic element as claimed in claim 10, wherein the high-frequency inductive electronic is capable of operating in a high frequency that is from 50 k Hz to 200 k Hz.

14. The high-frequency inductive electronic element as claimed in claim 10, wherein the magnetic coating layer further has insulating coating and the non-conductive magnetic material distributed homogeneously in the insulating coating and has 30˜50% solid content relative to the insulating coating;
wherein the magnet wire is manufactured by a method comprising providing the conductor; coating the conductor with the coating layer that each layer is rapidly coated for more than one times; and instantly drying the coating layer at 440˜500° C. to form the magnet wire.

15. The high-frequency inductive electronic element as claimed in claim 14, wherein the magnetic coating layer is formed by surface treating the non-conductive magnetic material with surfactant; and homogeneously blending the non-conductive magnetic material and the insulating coating.

16. The high-frequency inductive electronic element as claimed in claim 15, wherein the surfactant is selected from the group consisting of silane and oleic acid.

17. The high-frequency inductive electronic element as claimed in claim 10, wherein
the non-conductive magnetic material of the magnetic coating layer comprises ferromagnetism or ferrimagnetism and the non-conductive magnetic material comprises multiple particles with an average size of 3 μm;
the insulating coating of the magnetic coating layer is made of polyester, polyimide, polyurethane, poly(amide-imide) or poly(ester-imide); and
the insulating coating layer is made of polyester, polyimide, polyurethane, poly(amide-imide) or poly(ester-imide).

18. The high-frequency inductive electronic element as claimed in claim 16, wherein the non-conductive magnetic material is selected from the group consisting of γ-Fe₂O₃, Fe₃O₄, Ni—Zn ferrite, Mn—Zn ferrite, Mg—Zn ferrite, Ba ferrite and Sr ferrite.

19. The high-frequency inductive electronic element as claimed in claim 10, wherein the conductor is selected from the group consisting of cylindrical bare copper wire, flat bare copper wire, copper clad aluminum wire, aluminum wire, tinned copper wire and alloy metallic wire.

20. A method for manufacturing a magnetic enameled wire, comprising
providing the magnet wire as claimed in claim 1; and
magnetizing the non-conductive magnetic material in the magnetic coating layer of the magnet wire to lower alternative current (AC) resistance in the magnetic enameled wire in a high-frequency operation.
